(19) United States
(12) Patent Application Publication
(10) Pub. No.: US 2025/0286525 A1
(43) Pub. Date: Sep. 11, 2025

(54) AUTOMATIC EQUALIZATION OF OUTPUT VOLTAGE FOR CURRENT OUTPUT AMPLIFIER

(71) Applicant: SKYWORKS SOLUTIONS, INC., Irvine, CA (US)

(72) Inventors: Michael Jon Wurtz, Lake Oswego, OR (US); Evan Michael Albright, Portland, OR (US)

(21) Appl. No.: 19/069,886

(22) Filed: Mar. 4, 2025

Related U.S. Application Data
(60) Provisional application No. 63/561,452, filed on Mar. 5, 2024.

(51) Int. Cl. H03G 5/16; H03F 3/183

(52) U.S. Cl. CPC H03G 5/165; H03F 3/183; H03F 2200/03

(57) ABSTRACT

A system for determining an error in an electrical signal is presented, including: an input configured to receive an input signal; an output configured to provide an output signal; an equalizer coupled to the input; an amplifier coupled to the equalizer; and an error determination circuit coupled to the output, the input, and the equalizer.

### CROSS-REFERENCE TO RELATED APPLICATIONS

This application claims priority under 35 U.S.C. § 119(e) to U.S. Provisional Application No. 63/561,452, filed on Mar. 5, 2024 and titled AUTOMATIC EQUALIZATION OF OUTPUT VOLTAGE FOR CURRENT OUTPUT AMPLIFIER, which is hereby incorporated by reference in its entirety for all purposes.

### BACKGROUND

### 1. Field of the Disclosure

At least one example in accordance with the present disclosure relates generally to equalization of electric signals in electronic devices.

### 2. Discussion of Related Art

Signal equalization involves adjusting the characteristics of a signal (such as an audio signal) to attenuate some frequencies and/or provide gain to other frequencies.

### SUMMARY

According to at least one aspect of the present disclosure, a system for determining an error in an electrical signal, the system comprising: an input configured to receive an input signal; an output configured to provide an output signal; an equalizer coupled to the input; an amplifier coupled to the equalizer; and an error determination circuit coupled to the output, the input, and the equalizer.

According to at least one aspect of the present disclosure, a system for determining an error in an electrical signal is presented, the system comprising: an input; an output impedance; an equalizer coupled to the input; an amplifier coupled to the equalizer and to the output impedance; and an error determination circuit coupled to the input, output impedance, and equalizer, the error determination circuit including: an analog-to-digital converter (ADC), a time domain error metric circuit coupled to the ADC, a dual-channel digital Fourier Transform engine coupled to the ADC, and an equalization updater coupled to the time domain error metric circuit and the dual-channel digital Fourier Transform engine.

According to at least one aspect of the present disclosure, a process for adjusting the equalization of an electrical signal is presented, comprising: determining whether it is time to check for an error between an input signal and an output signal; responsive to determining that it is time to check for an error, determining the error between the input signal and the output signal; responsive to determining the error, determining whether the error exceeds a threshold error; responsive to determining that the error exceeds the threshold error, estimating an impedance of a load; responsive to determining the impedance, determining one or more coefficients for a discrete Fourier Transform (DFT); and responsive to determining the one or more coefficients, controlling an equalizer to adjust the input signal based on the one or more coefficients.

In some examples, determining whether it is time to check for an error includes basing the time on one or more of a clock signal, a first sensor reading detecting a change in the output signal or the input signal, a second sensor reading detecting a change in an ambient condition, or a third sensor reading detecting a change in a condition of the load. In some examples, determining the error includes comparing the input signal to the output signal to determine one or more of a difference or ratio between the input signal and the output signal. In some examples, determining whether the error exceeds the threshold error includes comparing the error to the threshold error. In some examples, the threshold error is determined based on a maximum error chosen for an application. In some examples, estimating the impedance of the load includes estimating the impedance based on an output of an equalizer and the output signal. In some examples, determining controlling the equalizer includes providing the equalizer with control inputs that change a transfer function of the equalizer. In some examples, the error is checked periodically. In some examples, the process of described above may be performed by the systems described herein and above.

According to at least one aspect of the present disclosure, a system for determining an error in an electrical signal is provided, the system comprising a first input connection configured to receive an input signal; a second input connection configured to receive an output signal; an error determination circuit (“EDC”) configured to output an update signal based on the input signal, the output signal, and an equalized signal; an equalizer with configurable coefficients, the equalizer configured to adjust the configurable coefficients based on the update signal, and to output the equalized signal based on the configurable coefficients and the input signal.

In some examples, the EDC includes an analog-to-digital converters (“ADC”) configured to convert the output signal from analog to digital form into a converted output signal, and to output the converted output signal. In some examples, the EDC further includes a first circuit configured to determine a first error value based on a difference, in the time domain, between the converted output signal and the input signal; and a second circuit configured to perform a Fourier transformation based on the converted output signal and the equalized signal, wherein performing the Fourier transformation includes determining one or more Fourier coefficients. In some examples, the EDC further includes a third circuit configured to receive the first error value from the first circuit, and to receive at least one of a result of the Fourier transformation or the one or more Fourier coefficients from the second circuit, and further configured to output the update signal. In some examples, the EDC is further configured to, based on the first error value and at least one of the result of the Fourier transformer or the one or more Fourier coefficients, determine a set of coefficients to replace one or more of the configurable coefficients, and to provide the set of coefficients via the update signal to the equalizer. In some examples, the first circuit determines the first error value based on a weighted average of an input voltage and an output voltage. In some examples, the system further comprises an amplifier configured to condition the equalized signal to produce a conditioned signal, and output the conditioned signal to a load. In some examples, the conditioned signal includes a driving current, the amplifier being configured to provide the driving current to the load. In some examples, the output signal is provided by a load. In some examples, the system further comprises a load, wherein the load includes at least one electro-mechanical component.

According to at least one aspect of the present disclosure, a process for adjusting the equalization of an electrical signal is presented, comprising determining whether it is time to check for an error between an input signal and an output signal, the output signal provided by a load; determining the error between the input signal and the output signal; responsive to determining the error, determining whether the error exceeds a threshold error; determining an impedance of the load; determining one or more coefficients for a discrete Fourier Transform (DFT) based at least in part on the impedance of the load; and controlling an equalizer to adjust the input signal based on the one or more coefficients.

In some examples, determining whether it is time to check for an error includes basing the time on one or more elements of a set, the elements of the set including a clock signal, a change in the output signal or the input signal, a change in an ambient condition, and a change in a condition of the load. In some examples, the change in the ambient condition includes a change in a temperature. In some examples, determining the error includes comparing the input signal to the output signal to determine one or more of a difference or ratio between the input signal and the output signal. In some examples, estimating the impedance of the load includes estimating the impedance based on an output of an equalizer and the output signal.

According to at least one aspect of the present disclosure, a method of adjusting equalization of an input signal is presented, comprising equalizing the input signal to produce an equalized signal via an equalizer; converting an output signal from analog to digital form to produce a converted signal; determining an error value in the time domain based on the converted signal and the equalized signal; determining a Fourier transformation of the converted signal; determining at least one adjustment to at least one coefficient of the equalizer based on the error value and the Fourier transformation; and updating the at least one coefficient of the equalizer to reflect the at least one adjustment and to thereby alter the equalized signal.

In some examples, the output signal is provided by a load, the load being driven by a driving current that is based on the equalized signal. In some examples, the error value is a weighted average of an input voltage of the input signal and an output voltage of the output signal. In some examples, determining the Fourier transformation includes determining one or more Fourier coefficients, and determining the at least one adjustment to at least one coefficient of the equalizer includes determining the at least one adjustment based on the one or more Fourier coefficients. In some examples, updating the at least one coefficient of the equalizer includes replacing the at least one coefficient with at least one new coefficient of the one or more coefficients.

### BRIEF DESCRIPTION OF THE DRAWINGS

Various aspects of at least one embodiment are discussed below with reference to the accompanying figures, which are not intended to be drawn to scale. The figures are included to provide an illustration and a further understanding of the various aspects and embodiments, and are incorporated in and constitute a part of this specification, but are not intended as a definition of the limits of any particular embodiment. The drawings, together with the remainder of the specification, serve to explain principles and operations of the described and claimed aspects and embodiments. In the figures, each identical or nearly identical component that is illustrated in various figures is represented by a like numeral. For purposes of clarity, not every component may be labeled in every figure. In the figures:

FIG. 1 illustrates a system for equalizing current according to an example;

FIG. 2 illustrates a system for equalizing current according to an example;

FIG. 3 illustrates a process for adjusting an equalization according to an example; and

FIG. 4 illustrates an error metric according to an example.

### DETAILED DESCRIPTION

In some circuits that include electro-mechanically coupled components (“electro-mechanical components”), driving the electro-mechanical components based on a current may be used in lieu of, or in addition to, driving the electro-mechanical components with a voltage. That is, the circuit may use a current, in a current drive mode, to control the operation of the electro-mechanical component, and may use a voltage, in a voltage drive mode, to control the operation of the electro-mechanical component.

In some examples, current drive mode may offer advantages over voltage drive mode. For example, in audio applications, an output element, such as a transducer or a moving armature, may generate an audio signal at audible or inaudible frequencies and volumes. However, when using a voltage to drive the circuit, non-linear characteristics of the electro-mechanical components of the circuit may generate an electromotive force (EMF) that opposes the voltage and may introduce error (in the form of distortion or noise) into the audio signal. This is because the “back” EMF generated by the non-linearities can effectively alter the voltage used to drive the circuit by increasing or decreasing the driving voltage.

On the other hand, a driving current is not affected by the back EMF, and so the audio signal is generally not distorted to the degree that would be present when using a driving voltage. However, when generating a driving current using a current-controlled amplifier, the audio signal may be proportional to the impedance of the output element. In some examples, the audio signal may be directly proportional to the impedance of the output element. The impedance of the output element (e.g., an electro-acoustic transducer) may vary significantly depending the temperature of the output element. In some examples, equalizing using an equalizer to account for the response of the circuit in current drive mode can be used to improve the audio signal. However, if the temperature of the output element causes the main resonance frequency of the output element to shift, equalization can actually result in more error than would be present using a driving voltage.

Aspects of the present disclosure relate to a system for driving an output element with mechanical and/or moving elements, such as a voice coil and diaphragm, moving armature, and so forth, using a current wherein the error caused by equalization is minimized or eliminated by using auto-equalization to adjust for changes in the temperature of the output element that cause changes to the impedance of the output element.

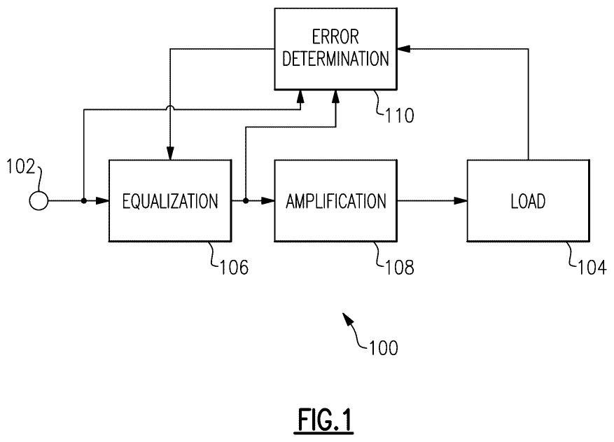

FIG. 1 illustrates a system 100 for equalizing a current to account for variations in the load impedance (e.g., of the output element) caused by variations in the temperature of the output element according to an example. The system 100 includes an input 102, a load 104, an equalizer 106, an amplifier 108, and an error determination circuit 110 (“EDC 110”).

In some examples, the system 100 is configured to reduce an error between an input signal at the input 102 and an output signal at the load 104. The output signal may vary with the temperature of the load 104. To reduce the error, the EDC 110 may compare the input signal to the output signal and then adjust the performance and/or behavior of the equalizer 106 to reduce the difference between the input and output signals.

The input 102 is coupled to the equalizer 106 and the EDC 110. The equalizer 106 (“Equalization”) is coupled to the input 102, the EDC 110, and the amplifier 108 (“Amplification”). The amplifier 108 is coupled to the load 104. The load 104 is coupled to the amplifier 108 and to the EDC 110. The EDC 110 is coupled to the input 102, the equalizer 106, and the load 104.

The input 102 is configured to receive an input signal. The input signal may have frequency characteristics, voltage characteristics, and/or current characteristics. The input signal may be indicative of desired characteristics of the output signal (e.g., it may be desired that the input signal and output signal be substantially identical or minimally deviate from one another).

The load 104 may be an electro-mechanical component (e.g., a voice diaphragm). The load may be configured to receive a voltage and/or current signal (or other signal) from the amplifier 108. The load 104 may have an impedance that varies according to certain conditions (for example, temperature). The load 104 may be configured to provide a signal to the EDC 110 indicative of a voltage, current, or other characteristic of the load 104. For example, the load 104 may be configured to provide a signal to the EDC 110 indicative of the voltage across the electro-mechanical component (e.g., impedance) of the load 104.

The equalizer 106 is configured to equalize the input signal based on the output of the EDC 110 and to provide an equalized signal to the amplifier 108. In some examples, the equalizer has a transfer function that corresponds to the adjustments made by the equalizer 106 to the input signal. The transfer function of the equalizer 106 may be based on the filter coefficients of and/or in use by the equalizer 106. The equalizer 106 may also be configured to provide the equalized signal (or a signal derived therefrom) to the EDC 110. In some examples, the equalizer 106 may provide a current to the EDC 110.

The amplifier 108 is configured to receive the equalized signal from the equalizer 106, perform various operations on the equalized signal, and produce an adjusted signal (the “second signal”) to provide to the load 104 and/or to the EDC 110. The amplifier 108 may, for example, modulate the equalized signal (e.g., via Delta-Sigma Modulation), perform element matching using the equalized signal, convert the equalized signal from digital-to-analog form or from analog-to-digital form, interpolate the equalized signal, provide gain or attenuation to the equalized signal, generate drive signals based on the equalized signal, and so forth.

The EDC 110 is configured to receive various feedback signals (for example, the input signal, the equalized signal, the output signal, signals based thereon, and so forth) and then correct the equalization used by the equalizer 106 to account for variations in the impedance of the load 104 (e.g., variations due to temperature). The EDC 110 may provide control signals to the equalizer 106 to alter the equalization provided by the equalizer 106 to take into account the corrections determined by the EDC 110. In some examples, the inputs to the EDC 110 include at least one input signal indicative of a current (for example, a current provided by the equalizer 106), and at least one signal indicative of a voltage (for example, a voltage present within the amplifier and/or at an output of the amplifier 108 and/or at the load 104.

In some examples, the EDC 110 may compare the error between the input and output signals and, responsive to determining that the error exceeds an error threshold, the EDC 110 may determine a set of coefficients to adjust the transfer function of the equalizer 106 and apply those coefficients to the equalizer 106.

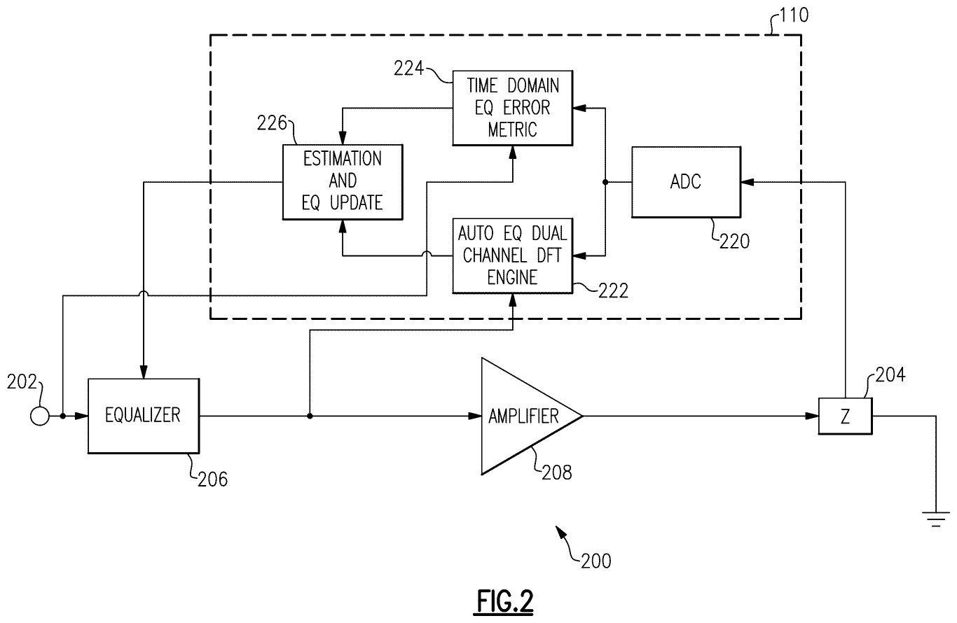

FIG. 2 illustrates a system 200 for equalizing a current to account for variations in temperature of the output element according to an example.

The system 200 includes an input 202, a load 204, an equalizer 206, an amplifier 208, an interpolation circuit 210, an analog-to-digital converter 220 (“ADC 220”), a DFT engine 222, a time-domain error metric calculation circuit 224 (“TDEC 224”), and an equalization updater 226.

The input 202 is coupled to the equalizer 206 and the TDEC 224. The equalizer 206 is coupled to the DFT engine 222 and the amplifier 208. The amplifier 208 is coupled to the load 204. The load 204 is coupled to a reference node and to the ADC 220. The ADC 220 is coupled to the TDEC 224 and the DFT engine 222. The TDEC 224 is coupled to the equalization updater 226. The DFT engine 222 is coupled to the equalization updater 226. The equalization updater 226 is coupled to the equalizer 206.

The input 202 is configured to receive an input signal. The input signal may be digital or analog and may have various characteristics, such as voltage, current, and/or frequency components.

The equalizer 206 is configured to receive the input signal from the input 202 and to equalize the input signal to produce an equalized signal. The equalizer 206 may provide the equalized signal to the DFT engine 222 and/or amplifier 208. In some examples, the equalized signal provided by the equalizer 206 to the DFT engine 222 and/or amplifier 208 may be a digital signal, and may be configured to act as a proxy for current. The equalizer 206 may adjust the gain and/or attenuation of frequency components of the input signal. For example, the input signal may have multiple frequency components including a first frequency component and a second frequency component. The equalizer 206 may, for example, increase the gain of the first frequency component while attenuating the second frequency component, or may attenuate the first frequency component while increasing the gain of the second frequency component, or attenuate both frequency components, or increase the gain of both frequency components. The equalizer 206 may perform similar adjustments to any other frequency components of the input signal. In some examples, the equalizer 206 may have a transfer function that corresponds to the adjustments made by the equalizer to the input signal. The transfer function of the equalizer 206 may be determined by the filter coefficients of and/or in use by the equalizer 206.

To equalize the input signal, the equalizer 206 is further configured to receive an equalization update signal (“update signal”) from the equalization updater 226. The coefficients of the equalizer 206 may be changed based on the update signal, thereby adjusting the transfer function of the equalizer 206. For example, the equalizer 206 may use the update signal to adjust the gain and attenuation applied to the input signal. The equalizer 206 may adjust the gain and/or attenuation applied to one or more of the frequency components of the input signal based on the update signal.

The amplifier 208 is configured to amplify the equalized signal and/or the input signal (for example, in the case where the equalizer does not need to make any adjustments to the input signal). The amplifier 208 may, in some examples, be a fine-gain amplifier. The amplifier 208 may adjust the gain and/or attenuation of the equalized signal to an optimized level of gain and/or attenuation to produce the optimum peak height of the equalized signal. The amplifier 208 may then provide the output signal to the load 204.

The amplifier 208 may further condition the equalized signal (which may be the analog version of the equalized signal). The amplifier 208 may include various filters and other components that may adjust the characteristics of the equalized signal. The amplifier 208 may also include an analog-to-digital converter configured to convert the equalized signal from analog to digital form. The amplifier 208 may condition one or both the analog and digital forms of the equalized signal.

The load 204 may be an electro-mechanical component configured to receive the output signal (from the amplifier 208). The load 204 may have a temperature dependent impedance. The load 204 may be configured to provide a signal to the ADC 220 indicative of a characteristic of the output signal as applied to the load 204 (e.g., a voltage across the temperature-dependent impedance of the load 204).

The ADC 220 is an analog-to-digital converter configured to convert the output signal (as measured across the load 204) from analog form to digital form and provide the digitized version of the output signal to the DFT engine 222 and the TDEC 224.

The DFT engine 222 is configured to perform a discrete Fourier transform based on the equalized signal provided by the equalizer 206 and the digital version of the output signal provided by the ADC 220. In some examples, the DFT engine 222 may perform the discrete Fourier transform based on a signal indicative of a current (e.g., the output from the equalizer 206) and a signal indicative of a voltage (e.g., the output of the ADC 220) using a known method, such as Welch's Method.

The TDEC 224 is configured to compare the input signal from the input 202 to the output signal from the ADC 220 and determine the error between the signals. In some examples, the TDEC 224 determines the error between the signals in the time domain. In some examples, the error may be determined as a difference and/or proportion between two values, such as the input signal and the output signal. In some examples, the error may be an average or weighted value. For example, the error may be determined according to the equation:

$$Error = avg ( \frac{\vert {V}_{i n} - {V}_{o u t} \vert}{a v g ( {V}_{i n} )} ) \qquad ( 1 )$$

where Vᵢₙ is the voltage of the input signal, avg(Vᵢₙ) is the average value of Vᵢₙ over a given period of time, and Vₒᵤₜ is the voltage of the output signal.

The equalization updater 226 may be a microcontroller or processor in some examples. In some examples, the equalization updater 226 may be a RISC processor. The equalization updater 226 may receive the error measurement produced by the TDEC 224 and the output of the DFT engine 222 to determine the adjustments to make to the operation of the equalizer 206. The equalization updater 226 may provide the update signal to the equalizer 206 to control the behavior of the equalizer 206 (e.g., by changing the equalization characteristics of the equalizer 206, for example, by changing the coefficients which determine the transfer function of the equalizer 206).

In some examples, the EDC 110 of FIG. 1 may be implemented using the ADC 220, TDEC 224, DFT engine 222, and/or equalization updater 226.

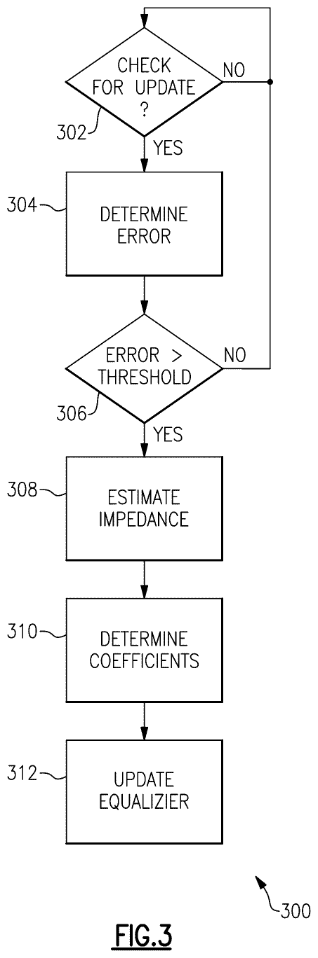

FIG. 3 illustrates a process 300 for auto-equalization to reduce the error between an input signal and an output signal according to an example. The process 300 may be performed using the system 100 or the system 200 disclosed herein, or any other similar system. In some examples, process 300 involves determining and/or sampling an input signal, an equalized signal, and/or an output signal, determining an error based on at least one of those signals, determining coefficients based on at least one of those signals, and then updating the coefficients of an equalizer (or similar device) to change the transfer function of the equalizer. For the purposes of illustration, the acts of process 300 shall make reference to the components of FIGS. 1 and 2.

At act 302, the EDC 110 determines whether it is time to check whether the error between the input and output signal exceeds a threshold error. The EDC 110 may have an internal clock or timer that triggers a check at intervals of time (e.g., the EDC 110 may check the error periodically). For example, a timer may output a signal at regular or irregular intervals indicating that the impedance should be updated, or the EDC 110 may determine that the impedance value is old and should be updated, or a sensor may detect a change, exceeding a threshold amount, of an ambient condition, such as temperature, and based on the detected change, determine that a recalculation should be performed, and so forth. In some examples, the EDC 110 may detect a change in the temperature of the load 104, 204 using a temperature sensor or similar device, and determine that it is time to check the error if the temperature has changed by more than a threshold temperature amount. Regardless of how the EDC 110 determines that it is time to check the error, if the EDC 110 determines that it is time to check the error (302 YES), the process 300 may continue to act 304. If the EDC 110 determines that it is not time to check the error (302 NO), the process 300 may return and/or remain at act 302.

At act 304, the EDC 110 determines the error between the input signal and the output signal. In some examples, the error may be determined by the TDEC 224. The EDC 110 may determine the error by comparing the input signal to the output signal, for example, by comparing a voltage of the input signal to a voltage of the output signal, or by comparing an average voltage of the input signal to an average voltage of the output signal. The EDC 110 may, for example, determine a difference and/or ratio between the input and/or output signal. In some examples, the EDC 110 may use equation (1) to determine the error. Once the EDC 110 has determined the error, the process 300 may continue to act 306.

At act 306 the EDC 110 determines whether the error exceeds an error threshold. If the error exceeds the error threshold (306 YES), the process 300 may continue to act 308. If the error does not exceed the error threshold (306 NO), the process 300 may return to act 302 or another, earlier act. The error threshold may be any desired value. In some examples, the error threshold may be a value chosen such that distortions due to the error are not audible and/or noticeable by a human. In other examples, the error threshold may be chosen based on a desired maximum error for a given application. The process 300 may then continue to act 308.

At act 308, the EDC 110 estimates the impedance of the load 104, 204. The impedance of the load 104, 204 may vary with temperature, and thus the EDC 110 may determine a different estimate of the impedance of the load 104, 204 every time the EDC 110 estimates the impedance. The impedance may be calculated with respect to one or more frequency ranges (sometimes referred to as frequency bins). The coherence of the load 104, 204 (e.g., a transducer of the load 104, 204) may also be determined. In some examples, the EDC 110 may estimate the impedance and/or coherence based on the output of the equalizer 106, 206 (e.g., the equalized signal) and the output of the ADC 220 (e.g., the digitized output signal provided from the load 104, 204). The process 300 may then continue to act 310.

At act 310, the EDC 110 determines the filter coefficients that may be used to adjust the transfer function of the equalizer 106, 206. In some examples, the filter coefficients are based on or correspond to the Fourier transform performed by the DFT engine 222. For example, the Fourier transform may produce various coefficients that can be used to estimate and/or determine a transfer function for the equalizer 106, 206 that will reduce the error between the input and the output signal. The process 300 may then continue to act 312.

At act 312, the EDC 110 (e.g., equalization updater 226) updates the coefficients of the equalizer 106, 206 to change the transfer function of the equalizer, such that the difference between the input signal and the output signal (e.g., the error) is reduced or eliminated. In some examples, the EDC 110 may adjust the coefficients of the equalizer 106, 206 by using a control signal to update the coefficients. In some examples, the coefficient portion of the equalizer 106, 206 may be incorporated into and/or shared with the EDC 110, and so forth.

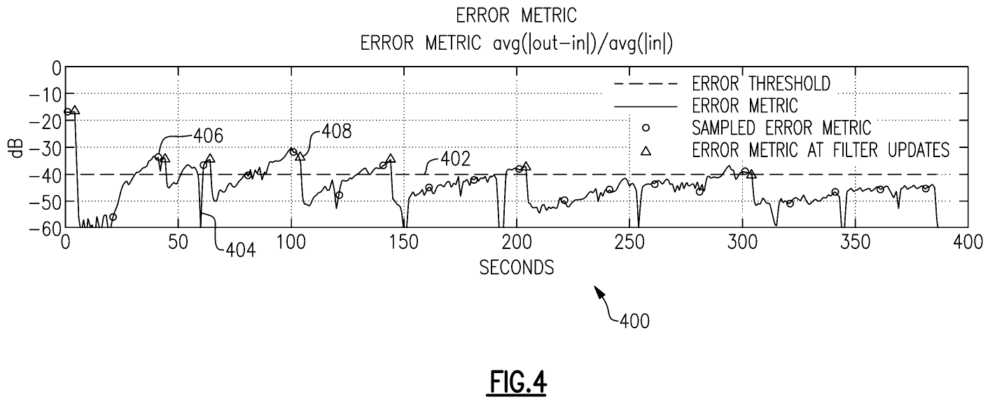

FIG. 4 illustrates a graph 400 depicting the timing of filter updates relative to an error between the input and output signals. The x-axis of the graph 400 depicts the passage of time in seconds. The y-axis of the graph 400 depicts the amount of error (e.g., the value of the error metric) in decibels (dB). A first trace 402 depicts an error threshold. The second trace 404 depicts the error metric (that is, the error between the first signal and second signal at a given point in time). A plurality of circular markings 406 (“circular markings 406”) depict when the error is checked and/or sampled (e.g., when the TDEC 224 and/or EDC 110 determine the error). A plurality of triangular markings 408 (“triangular markings 408”) depict when the EDC 110 and/or equalization updater 226 updates the coefficients of the equalizer 106, 206. It may be assumed that the state of the electro-mechanical component is changing during at least part of the time shown in the graph 400. That is, it may be assumed that the impedance of the electro-mechanical component is changing during at least a portion of the time depicted in the graph 400, for example, as a result of variations in ambient conditions such as temperature.

As shown in the graph, the triangular markings 408 indicating the updating of the coefficients occurs after the error is sampled, as indicated by the circular markings 406. However, the coefficients are not updated after every time the error is sampled (that is, sometimes no triangular marking appears directly after a circular marking). This is because, in the example depicted in graph 400, the system 100, 200 only updates the coefficients provided the sampled error exceeds the error threshold.

Furthermore, as shown in the graph 400, triangular markings 408 appear roughly the same amount of time after the circular markings 406 which proceed them for every circular-marking-triangular-marking pair. This indicates that, at least in some examples, the amount of time between checking the error and updating the filter coefficients (if the filter coefficients will be updated) is constant or approximately constant. That is, from determining that the error metric exceeds the error threshold, determining at least the impedance of the load 104, 204, determining the coefficients for the equalizer 106, 206, and/or applying the coefficients to the equalizer 106, 206 may all occur within a very short period of time after sampling the error.

In general, after updating the filter coefficients, the error metric (e.g., trace 404) decreases. In general, when the coefficients of the equalizer 106, 206 are updated, the adjustments cause the output of the equalizer and the output of the system to become closer together, thus reducing the error metric as the difference between the two signals decreases (e.g., the error between the input signal and output signal decreases).

As further demonstrated by the graph 400, as successive updates are made to the coefficients, the system will tend to stabilize such that further updates are not required. For example, between the 0 second mark and the 200 second mark, there are six (6) updates of the coefficients, whereas, between 200 seconds and 400 seconds there are only two (2) updates of the coefficients. Thus, as the load 104, 204 temperature changes, the polling rate may be adjusted (e.g., reduced or increased). For example, if the temperature tends to stabilize (remain constant), the polling rate may be reduced, while if the temperature tends to change more quickly, the polling rate may be increased.

Consider, for example, ordinary use of an audio system, where the output signal itself may cause the load 104, 204 to heat up (e.g., due to heat transfer from the current). As the load 104, 204 heats up, the load 104, 204 may tend to reach a point of equilibrium where the temperature of the load 104, 204 no longer changes (or changes at a slow rate). As a result, fewer or no further updates to the coefficients of the equalizer 106, 206 may be required during an extended period of time (absent external changes in temperature or other ambient conditions, or significant changes in how much power the load 104, 204 is consuming).

Examples of the methods and systems discussed herein are not limited in application to the details of construction and the arrangement of components set forth in the following description or illustrated in the accompanying drawings. The methods and systems are capable of implementation in other embodiments and of being practiced or of being carried out in various ways. Examples of specific implementations are provided herein for illustrative purposes only and are not intended to be limiting. In particular, acts, components, elements and features discussed in connection with any one or more examples are not intended to be excluded from a similar role in any other examples.

Also, the phraseology and terminology used herein is for the purpose of description and should not be regarded as limiting. Any references to examples, embodiments, components, elements or acts of the systems and methods herein referred to in the singular may also embrace embodiments including a plurality, and any references in plural to any embodiment, component, element or act herein may also embrace embodiments including only a singularity. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items.

References to “or” may be construed as inclusive so that any terms described using “or” may indicate any of a single, more than one, and all of the described terms. In addition, in the event of inconsistent usages of terms between this document and documents incorporated herein by reference, the term usage in the incorporated features is supplementary to that of this document; for irreconcilable differences, the term usage in this document controls.

Various controllers, such as a controller (e.g. a processor, microprocessor, microcontroller, ASIC, FPGA, and so forth), may execute various operations discussed above. Using data stored in associated memory and/or storage, the controller also executes one or more instructions stored on one or more non-transitory computer-readable media, which the controller may include and/or be coupled to, that may result in manipulated data. In some examples, the controller may include one or more processors or other types of controllers. In one example, the controller is or includes at least one processor. In another example, the controller performs at least a portion of the operations discussed above using an application-specific integrated circuit tailored to perform particular operations in addition to, or in lieu of, a general-purpose processor. As illustrated by these examples, examples in accordance with the present disclosure may perform the operations described herein using many specific combinations of hardware and software and the disclosure is not limited to any particular combination of hardware and software components. Examples of the disclosure may include a computer-program product configured to execute methods, processes, and/or operations discussed above. The computer-program product may be, or include, one or more controllers and/or processors configured to execute instructions to perform methods, processes, and/or operations discussed above.

Having thus described several aspects of at least one embodiment, it is to be appreciated various alterations, modifications, and improvements will readily occur to those skilled in the art. Such alterations, modifications, and improvements are intended to be part of, and within the spirit and scope of, this disclosure. Accordingly, the foregoing description and drawings are by way of example only.

1. A system for determining an error in an electrical signal, the system comprising:
a first input connection configured to receive an input signal;
a second input connection configured to receive an output signal;
an error determination circuit (“EDC”) configured to output an update signal based on the input signal, the output signal, and an equalized signal;
an equalizer with configurable coefficients, the equalizer configured to adjust the configurable coefficients based on the update signal, and to output the equalized signal based on the configurable coefficients and the input signal.

2. The system of claim 1 wherein the EDC includes an analog-to-digital converter (“ADC”) configured to convert the output signal from analog to digital form into a converted output signal, and to output the converted output signal.

3. The system of claim 2 wherein the EDC further includes
a first circuit configured to determine a first error value based on a difference, in the time domain, between the converted output signal and the input signal; and
a second circuit configured to perform a Fourier transformation based on the converted output signal and the equalized signal, wherein performing the Fourier transformation includes determining one or more Fourier coefficients.

4. The system of claim 3 wherein the EDC further includes a third circuit configured to receive the first error value from the first circuit, and to receive at least one of a result of the Fourier transformation or the one or more Fourier coefficients from the second circuit, and further configured to output the update signal.

5. The system of claim 4 wherein the EDC is further configured to, based on the first error value and at least one of the result of the Fourier transformer or the one or more Fourier coefficients, determine a set of coefficients to replace one or more of the configurable coefficients, and to provide the set of coefficients via the update signal to the equalizer.

6. The system of claim 3 wherein the first circuit determines the first error value based on a weighted average of an input voltage and an output voltage.

7. The system of claim 1 further comprising an amplifier configured to condition the equalized signal to produce a conditioned signal, and output the conditioned signal to a load.

8. The system of claim 7 wherein the conditioned signal includes a driving current, the amplifier being configured to provide the driving current to the load.

9. The system of claim 1 wherein the output signal is provided by a load.

10. The system of claim 1 further comprising a load, wherein the load includes at least one electro-mechanical component.

11. A process for adjusting the equalization of an electrical signal, comprising:
determining whether it is time to check for an error between an input signal and an output signal, the output signal provided by a load;
determining the error between the input signal and the output signal;
responsive to determining the error, determining whether the error exceeds a threshold error;
determining an impedance of the load;
determining one or more coefficients for a discrete Fourier Transform (DFT) based at least in part on the impedance of the load; and
controlling an equalizer to adjust the input signal based on the one or more coefficients.

12. The process of claim 11 wherein determining whether it is time to check for an error includes basing the time on one or more elements of a set, the elements of the set including
a clock signal,
a change in the output signal or the input signal,
a change in an ambient condition, and
a change in a condition of the load.

13. The process of claim 12 wherein the change in the ambient condition includes a change in a temperature.

14. The process of claim 11 wherein determining the error includes comparing the input signal to the output signal to determine one or more of a difference or ratio between the input signal and the output signal.

15. The process of claim 11 wherein determining the impedance of the load includes estimating the impedance based on an output of an equalizer and the output signal.

16. A method of adjusting equalization of an input signal, comprising:
equalizing the input signal to produce an equalized signal via an equalizer;
converting an output signal from analog to digital form to produce a converted signal;
determining an error value in the time domain based on the converted signal and the equalized signal;
determining a Fourier transformation of the converted signal;
determining at least one adjustment to at least one coefficient of the equalizer based on the error value and the Fourier transformation; and
updating the at least one coefficient of the equalizer to reflect the at least one adjustment and to thereby alter the equalized signal.

17. The method of claim 16 wherein the output signal is provided by a load, the load being driven by a driving current that is based on the equalized signal.

18. The method of claim 16 wherein the error value is a weighted average of an input voltage of the input signal and an output voltage of the output signal.

19. The method of claim 16 wherein determining the Fourier transformation includes determining one or more Fourier coefficients, and determining the at least one adjustment to at least one coefficient of the equalizer includes determining the at least one adjustment based on the one or more Fourier coefficients.

20. The method of claim 19 wherein updating the at least one coefficient of the equalizer includes replacing the at least one coefficient with at least one new coefficient of the one or more coefficients.
